(19) United States
(12) Patent Application Publication
(10) Pub. No.: US 2009/0230510 A1
(43) Pub. Date: Sep. 17, 2009

(54) SEMICONDUCTOR STORAGE DEVICE AND METHOD OF MANUFACTURING THE SAME

(75) Inventors: Hiroshi Miki, Chiyoda-ku (JP); Tomoko Sekiguchi, Chiyoda-ku (JP); Naomi Inada, Chiyoda-ku (JP); Mitsuhiro Horikawa, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/400,553

(22) Filed: Mar. 9, 2009

(30) Foreign Application Priority Data
Mar. 11, 2008 (JP) 2008-061077

(51) Int. Cl. H01L 29/92; H01L 21/02; H01L 21/31; H01L 27/108

(52) U.S. Cl. 257/532; 438/396; 438/785; 257/296; 257/E29.342; 257/E21.008; 257/E21.24; 257/E27.084

(57) ABSTRACT

A rutile phase can be formed even in the case of a thin film by adding nickel or cobalt to titanium dioxide in the range of 0.5 to 10 atm %, and the use of this element-added titanium dioxide film in a capacitor dielectric film results in an increase in capacitance per unit area of a DRAM memory cell and enables a high-integration DRAM to be realized at low cost.

### BACKGROUND OF THE INVENTION

1. Field of the Invention

The present invention relates to a dynamic random access memory (hereinafter referred to as a DRAM) and, more particularly, to a capacitor for information storage that, along with an MOS transistor, constitutes a memory cell

2. Related Art

A memory cell of a DRAM can be comprised of an MOS transistor and a capacitor in a pair. To achieve high integration of DRAMs, it is necessary that capacitors also be miniaturized in addition to the miniaturization of MOS transistors. In this miniaturization of the memory cell, the shorter the gate length of the MOS transistor, the more the performance of the MOS transistor will be improved, whereas for a capacitor, a reduction of area simply causes a decrease in capacitance. On the other hand, even when a memory cell is miniaturized, it is necessary that the capacitance per cell be at least approximately 25 fF to avoid data errors due to various kinds of noises and to maintain refresh intervals. Therefore, a technique for increasing the capacitance per unit area is indispensable for the miniaturization of a memory cell.

There are two approaches to this problem. One is to make the electrode of a capacitor in a stereoscopic design, whereby the electrode is given a structure which is such that an effective surface area does not decrease even when the plane projected area is reduced. Techniques, such as a stacked capacitor structure, a trench capacitor structure and a roughened surface electrode, have been developed and used in the production of DRAMs. The other is to increase capacitance by raising the dielectric constant ε of dielectrics that constitute a capacitor, and alumina (ε≅9) and hafnium dioxide (ε≅20) are used as dielectric materials that replace silicon dioxide (ε≅4).

In the application of materials having a high dielectric constant in the latter approach, it is necessary to pay attention to the fact that there is the phenomenon that the electrode surface is a little eroded due to factors ascribed to manufacturing processes and an interface layer having a low dielectric constant is formed, with the result that the dielectric constant decreases substantially. Particularly, in a capacitor in which polycrystalline silicon is used as the electrode, it becomes impossible to take advantage of a high dielectric constant due to the effect of silicon dioxide formed at an interface.

For this reason, in a fine memory cell whose minimum fabrication dimension is not more than 0.1 μm, for example, the material for electrodes has come to be changed from the conventional polycrystalline silicon to corrosion-resistant metals. For example, according to Technical Digest of IEDM 2003, pp. 661-664, it is reported that a capacitor, in which titanium nitride and hafnium dioxide are used as such a metal electrode and materials having a high dielectric constant, respectively, are promising in the manufacture of DRAMs.

As materials having a higher dielectric constant, according to the 36th European Solid-State Device Research Conference, pp. 146-149, zirconium dioxide that crystallizes into a tetragonal crystal has been proposed. A stable phase of zirconium dioxide at room temperature is a monoclinic crystal having a dielectric constant similar to that of hafnium dioxide. However, according to Technical Digest of IEDM 2006, Session 9, Paper 7, it is stated that the tetragonal crystal becomes stable when the physical film thickness of a dielectric film is not more than several tens of nanometers and hence it becomes possible to utilize a higher dielectric constant (ε≅40).

However, when the miniaturization of DRAMs goes forward further, the insufficiency of capacitance becomes remarkable even when these techniques for increasing the dielectric constant are adopted. Therefore, in order to further improve a dielectric constant, the present inventors examined titanium dioxide as a dielectric film. In titanium dioxide, there are two types of crystal: orthorhombic anatase (ε≅30) that is formed when synthesis is performed at temperatures of not less than approximately 600° C. and tetragonal rutile (ε=170 in a direction parallel to the c-axis, ε≅90 in a vertical direction) that is formed at temperatures of not less than 700° C. Mixtures of the two crystal forms are obtained in the temperature range of 600° C. to 700° C. Consequently, it is understood that in order to obtain a dielectric constant exceeding that of zirconium dioxide of the related art, it is necessary to form a rutile type by subjecting titanium dioxide to heat treatment at temperatures of not less than 700° C.

Hence the present inventors carried out experiments to form thin films of titanium dioxide. For a dielectric thin film of a DRAM capacitor, it is necessary that the film thickness be as small as possible in order to increase capacitance. Therefore, the present inventors conducted an experiment in which the film thickness was changed in a wide range of 200 nm to not more than 10 nm. As a result, the inventors found out a phenomenon that the dielectric constant decreases suddenly, with 50 nm being a threshold value, in contrast to the above-described case of zirconium dioxide. The inventors conducted a further detailed study and as a result, it became evident that this phenomenon is caused by the fact that the smaller the physical film thickness, the more difficult the crystallization of titanium dioxide will be. That is, the inventors found out a new problem that in zirconium dioxide of the related art, a tetragonal crystal having a high dielectric constant tends to be generated by making the film thickness small, whereas in the case of titanium dioxide, conversely, a tetragonal crystal having a high dielectric constant is not formed any more.

### SUMMARY OF THE INVENTION

An example of representative means among semiconductor storage devices disclosed in the present invention is shown follows. That is, the semiconductor storage device related to the present invention is a semiconductor storage device provided with a DRAM cell having a capacitor including a lower electrode, a dielectric film and an upper electrode, in which the dielectric film contains titanium dioxide as a main component and further contains either nickel or cobalt.

The present invention is briefly described here. That is, the present invention provides a method of ensuring crystallinity sufficient for obtaining a high dielectric constant even a film is made thin in a film thickness capable of being applied to a capacitor of a DRAM cell. From detailed studies by the present inventors, this is achieved by causing cobalt or nickel to be contained. This cobalt or nickel is hereinafter referred to as an additive element. A preferred addition method and additive amount of the additive elements and a method of packaging in a DRAM memory cell will become apparent in exemplary embodiments.

By applying a capacitor of the above-described structure to a memory cell of a DRAM, it becomes possible to obtain signals necessary for actions of a memory even in a fine memory cell having a minimum fabrication dimension of not more than 60 nm, for example.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a sectional view of a DRAM memory cell showing an example of a semiconductor storage device related to the present invention;

FIGS. 2 to 8 are sectional view to explain a manufacturing process of the DRAM memory cell shown in FIG. 1;

FIG. 9 is a diagram showing the relationship between the capacitance and physical film thickness of an element-added titanium dioxide film used in a semiconductor storage device related to the present invention;

FIG. 10 is a diagram showing the relationship between the dielectric constant and physical film thickness of an element-added titanium dioxide film used in a semiconductor storage device related to the present invention;

FIG. 11 is an X-ray diffraction diagram of an element-added titanium dioxide film used in a semiconductor storage device related to the present invention;

FIG. 12 is a diagram showing the dependence of the dielectric constant of a nickel-added titanium dioxide film used in a semiconductor storage device related to the present invention on the added-nickel composition;

FIG. 13 is a diagram showing the dependence of the dielectric constant of a cobalt-added titanium dioxide film used in a semiconductor storage device related to the present invention on the added-cobalt composition;

FIG. 14 is a diagram showing the procedure for supplying a raw material gas during the formation of a nickel-added titanium dioxide film used in a semiconductor storage device related to the present invention by ALD;

FIG. 15 is a diagram showing the procedure for supplying a raw material gas during the formation of a cobalt-added titanium dioxide film used in a semiconductor storage device related to the present invention by ALD;

FIG. 16 is a sectional view of a DRAM memory cell showing an example of a semiconductor storage device related to the present invention;

FIGS. 17 to 23 are sectional views of the DRAM memory cell shown in FIG. 16 during manufacturing;

FIG. 24 is a sectional view of a DRAM memory cell showing an example of a semiconductor storage device related to the present invention;

FIG. 25 is a sectional view of a DRAM memory cell showing an example of a semiconductor storage device related to the present invention; and

FIG. 26 is a sectional view of a DRAM memory cell showing an example of a semiconductor storage device related to the present invention

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

Exemplary Embodiments of a semiconductor storage device according to the present invention will be described in detail below with reference to the accompanying drawings.

### Exemplary Embodiment 1

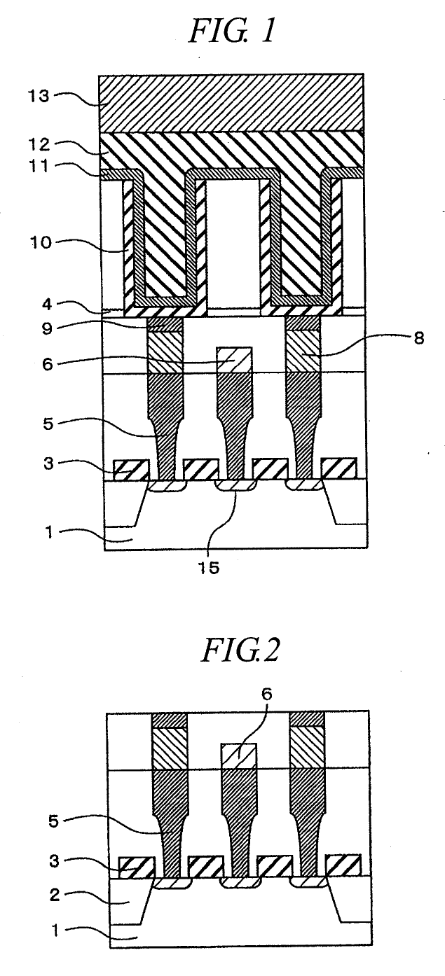

FIG. 1 is a sectional view of a semiconductor storage device, i.e., a DRAM in an exemplary embodiment. Bit line 6 is formed over silicon substrate 1. Word lines 3 that serves also as a gate electrode of a transistor are formed by a publicly-known method on silicon substrate 1, and first conductive plugs 5 formed from polysilicon are drawn from one side of transistor diffusion layers 15. Each second conductive plug 8 is connected to first conductive plug 5, and the second conductive plug is further connected to cylindrical capacitor lower electrode 10 via reactive barrier layer 9. Cobalt-added titanium dioxide 11 is formed on the surface of lower electrode 10, and upper electrode 12, lower electrode 10 and titanium dioxide 11 constitute a capacitor.

The manufacturing method of this DRAM cell will be described in detail below.

FIG. 2 shows a section obtained when the formation of the transistor of the memory cell, word lines 3, bit line 6, and interconnect plugs to the lower capacitor electrode has been completed. After the fabrication of isolation structure 2 and well structure (not shown) of the transistor in silicon substrate 1, word lines 3 that serve also as gate electrodes are fabricated. In gaps between the word lines, first conductive plugs (contact plugs) 5 to the bit line are formed from polysilicon.

The contact plug is formed by forming a through hole in interlayer insulating film 16 formed on silicon substrate 1 and by burying a polysilicon conductor in the through hole.

In this exemplary embodiment, the transistor has a publicly-known plane structure. However, the present invention can also be carried out by adopting a recess gate structure and a fin structure, which are known as means for suppressing the short channel effect.

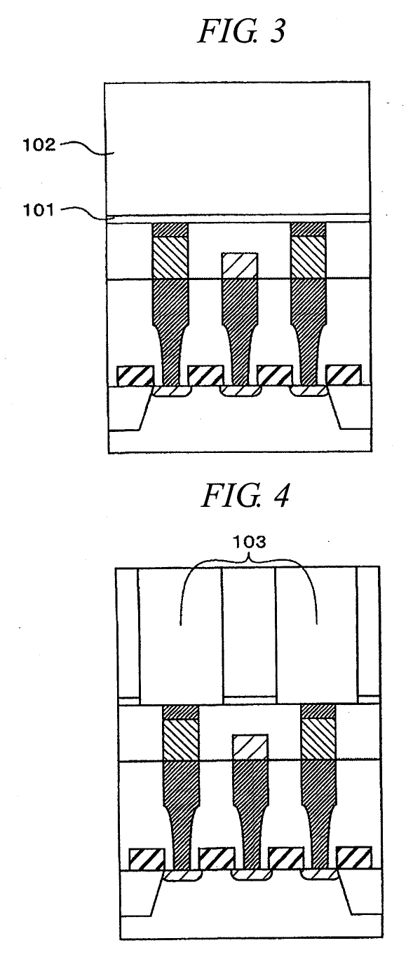

Next, an interlayer insulating film that determines the height of the capacitor electrode is deposited on the structure of FIG. 2. In this exemplary embodiment, silicon nitride layer 101 that becomes etching stopper layer 4 of FIG. 1 after fabrication and silicon oxide layer 102 are deposited. Silicon nitride layer 101 is deposited in film thicknesses of 5 nm to 10 nm by a CVD method (see FIG. 3). After that, silicon oxide layer 102 is deposited in thicknesses of 1 μm to 3 μm by a plasma CVD method using tetraethoxysilane and oxygen as raw materials. Silicon oxide layer 102 and silicon nitride layer 101 in portion 103 where the capacitor is to be formed are removed by photolithography and dry etching, whereby the structure shown in FIG. 4 is obtained. In FIGS. 1 to 8, to allow the FIGures to be seen easily, the film thickness and the length-to-width ratio are expressed on any given basis. However, because the formed hole structures are such that the diameter of the opening ranges from approximately 50 nm to 150 nm and the height ranges from 1 μm to 3 μm, the formed hole structures are very deep structures having the ratio of the opening to the depth (hereinafter referred to as an aspect ratio) which is as high as several tens.

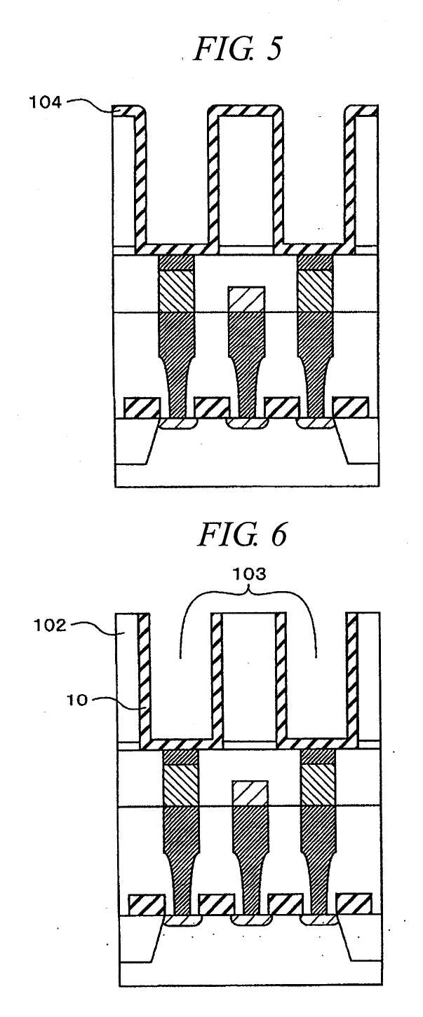

Next, ruthenium that becomes lower electrode 10 was deposited in a thickness of 10 nm by a CVD method (see FIG. 5). Although this ruthenium layer 104 is deposited by the CVD method using ethycyclopentadienyl ruthenium (Ru(EtCp)₂) and oxygen, ruthenium deposited by atomic layer deposition (hereinafter referred to as ALD) is also preferable. Although the deposition rate is lower than in the CVD method, the ALD method can take advantage of its feature of excellent step coverage when it is necessary to form uniformly a film also on the inner wall and bottom part of a structure having a very large aspect ratio as described above. For lower electrode 10, iridium and platinum can be mentioned as preferable materials in addition to ruthenium. For iridium, the CVD method using iridium acetylacetonato (Ir(acac)₃) and oxygen or the ALD method can be used. For platinum, the CVD method using platinum acetylacetonato (Pt(acac)₂) or trimethyl cyclopentadienyl platinum (PtCp(CH₃)₃) and oxygen or the ALD method can be used. In both cases, the film thickness is 10 nm, the same as in the use of ruthenium.

The etch back process is then performed in order to divide this lower electrode for each bit. After the application of a positive type photoresist onto the structure of FIG. 5, the whole chip surface is exposed by development, whereby the resist on silicon oxide film 102 is removed and an unexposed photoresist remains in the interior of hole structure 103. When this structure is dry etched, only the ruthenium layer between bits is removed and as shown in FIG. 6, a structure in which lower electrode 10 is divided for each bit can be formed.

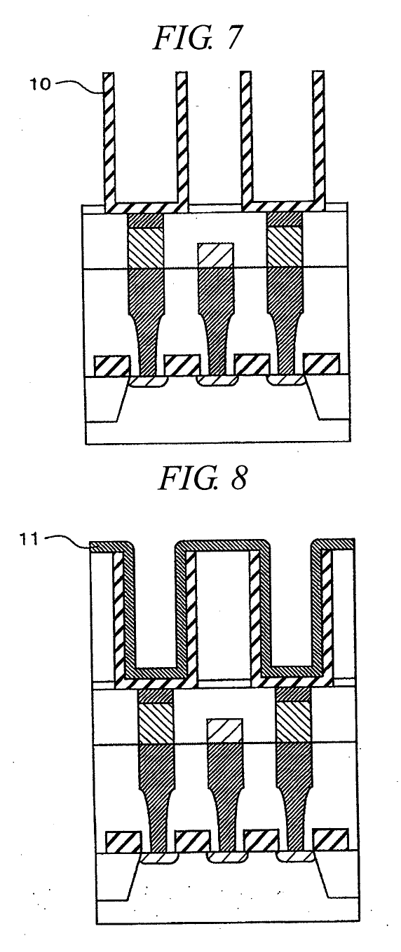

Furthermore, silicon oxide film 102 is removed by wet etching and the photoresist is removed, whereby it is also possible to form lower electrode structure 10 in which only ruthenium layer 104 remains in columnar shape (see FIG. 7). The making of this structure is also one of the exemplary embodiments. Although in this exemplary embodiment the description will be given below of a case where this removal of the silicon oxide layer is not performed, the following description will be applicable as it is even this removal of the silicon oxide layer is performed.

Next, a cobalt-added titanium dioxide layer, which a principal objective of the present invention, is formed. Titanium dioxide layer 11 to which 4% cobalt is added was formed in a thickness of 6 nm by the ALD method using a complex of cobalt, a complex of titanium and ozone as raw materials (see FIG. 8). The additive amount of cobalt was defined as the ratio of the number of cobalt atoms to the sum of the number of cobalt atoms and titanium atoms. The deposition temperature is 250° C. to 350° C. The effect that the oxidation of the ruthenium surface is suppressed is obtained due to such low deposition temperatures. After the finish of deposition, this cobalt-added titanium dioxide layer was caused to crystallize into rutile by two-stage treatment involving heat treatment in an oxidizing atmosphere at 500° C. and non-oxidizing heat treatment at 600° C. The dielectric constant after the crystallization was 60.

Similarly, the effect of the present invention is obtained also by using a nickel-added titanium dioxide layer in place of cobalt-added titanium dioxide layer 11. A titanium dioxide layer to which 2% nickel is added is formed in a thickness of 6 nm by the ALD method using a complex of nickel, a complex of titanium and ozone, and after the finish of deposition, the titanium dioxide layer is caused to crystallize into rutile similarly by two-stage heat treatment. The dielectric constant after the crystallization was 70. As with cobalt, the additive amount of nickel was defined as the ratio of the number of nickel atoms to the sum of the number of nickel atoms and titanium atoms.

The amount of cobalt to be added is determined by the relationship between the heat treatment temperature allowed for the crystallization of titanium dioxide into rutile, which is a phase having a high dielectric constant, and leakage current. This determination method will be described in detail in Exemplary Embodiment 2.

Furthermore, as upper electrode 12, ruthenium is formed by the CVD or ALD method. This step is preferably performed by the ALD method. The reason is as follows. The capacitor opening of FIG. 8 is narrowed by a ruthenium film and an element-added titanium dioxide film and is as narrow as less than 30 nm. On the other hand, the depth of the capacitor opening is as deep as several micrometers and hence this is a burying step with the highest aspect ratio. For this reason, the ALD method is desirable since step coverage is the most important film deposition characteristic in this step. However, because the deposition rate is low in the ALD method, it is also possible to further stack tungsten film 13 by the sputtering method in order to lower the sheet resistance as a plate electrode. The structure shown in FIG. 1 is completed after these steps. Incidentally, as materials for the upper electrode, iridium and platinum are preferable materials in addition to ruthenium, and formation by the ALD method is more desirable. It is not always necessary that the upper electrode and the lower electrode be made of the same material. For the lower electrode, it is necessary that the electrode be cut off for each bit, and microfabrication is necessary in this step. In this respect, ruthenium is more advantageous than other materials for the lower electrode. On the other hand, the necessity of microfabrication is small for the upper electrode and hence limiting factors of material selection are small. For this reason, for example, using platinum in the upper electrode alone and ruthenium in the lower electrode is an exemplary embodiment. Furthermore, it is not always necessary that the electrode material be a single film formed from any one of ruthenium, iridium and platinum, but the present invention is preferably carried out using a stacked film and an alloy film. Furthermore, for ruthenium and iridium, conductive oxides exist and it is also preferable to use these oxides in the electrode. A case where these oxides are part of a stacked electrode structure provides also a structure applicable to the present invention.

The accumulation capacitor capacitance obtained when a 4% cobalt-added titanium dioxide film having a thickness of 6 nm is used in a capacitor opening having 60 nm width and 2 μm depth becomes approximately 25 fF on average per bit, and it is possible to ensure a capacitance sufficient for a DRAM memory cell action. The capacitance obtained when a 2% nickel-added titanium dioxide film was used was approximately 30 fF. The leakage current obtained when in these capacitors a voltage of 0.5 V is applied across both electrodes is less than 1 fA per bit, and it is possible to make the refresh action intervals sufficiently long.

Incidentally, it was impossible to obtain a similar effect from pure titanium dioxide to which cobalt or nickel is not added. This is because heat treatment at not less than 700° C. is necessary for obtaining a rutile phase having a high dielectric constant. Delamination at an interface between ruthenium lower electrode 10 and barrier layer 9 occurs due to this heat treatment and contact resistance increases. The temperature at which this delamination occurs depends on the material for barrier layer 9 and film quality. In both titanium nitride and tantalum nitride, which are publicly-known nitride barrier materials, oxidation occurred due to heat treatment at 700° C. and nitrogen gas generated as a result of the oxidation caused delamination. In order to avoid this phenomenon, it is necessary to lower the heat treatment temperature. For example, delamination can be avoided by lowering the heat treatment temperature to the order of 450° C. In this case, however, anatase phase whose dielectric constant is approximately 30, a relatively small value, is formed. Therefore, the accumulation capacitor capacitance is on the order of 15 fF and a stable operation of the memory cell cannot be expected. Only lowering the crystallization temperature of rutile by using the additive elements of the present invention enables DRAM chips that operate stably to be produced by avoiding the problem of delamination.

### Exemplary Embodiment 2

In this exemplary embodiment, the dielectric characteristics of capacitors fabricated by using element-added titanium dioxide will be described in detail.

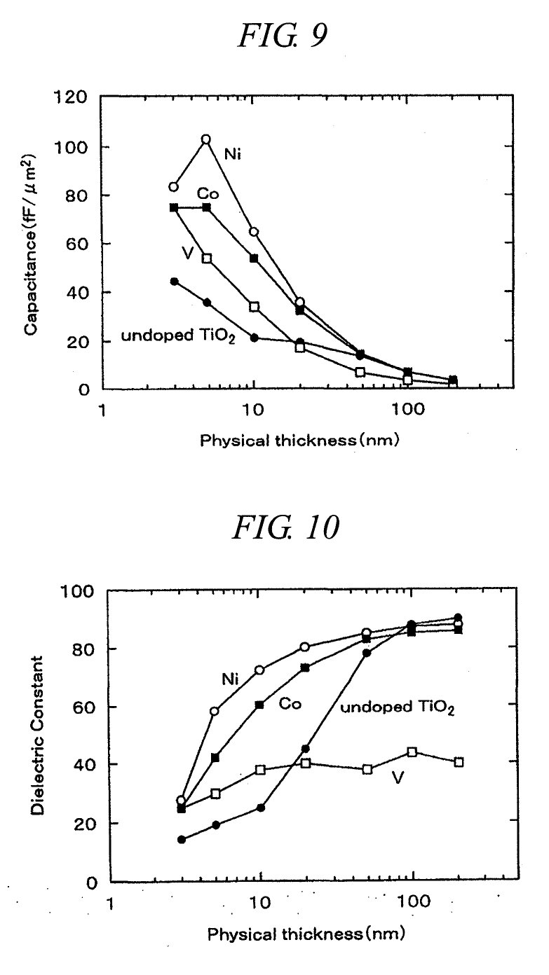

FIG. 9 shows the film thickness dependence of capacitance obtained when cobalt, nickel and vanadium are added to a titanium dioxide film. A pure titanium dioxide film is also shown for reference. The additive amount of cobalt, nickel and vanadium is 4%, 2% and 5%, respectively. The heat treatment temperature is 550° C. in the presence of additive elements but 800° C. only in the case of a pure titanium dioxide film. Because as described above the delamination of the lower electrode occurs when heat treatment at 800° C. is performed, the dielectric characteristics were measured by bringing a probe into direct contact with the ruthenium of the lower electrode without going through the barrier metal. In all of the cases, capacitance tends to increase with decreasing film thickness. The greatest thinned film effect is observed in nickel, cobalt is in the second order, and then vanadium comes next. From FIG. 9, the measurements were rearranged with dielectric constant as ordinate, as shown in FIG. 10. On the basis of this FIG. 10, a description will be given of a mechanism that is effective in improving dielectric constant in a region where the amounts of the additive elements are not more than 10 nm thick.

First, attention is paid to cases where the film thickness is large and on the order of 100 nm. There is scarcely any difference in dielectric constant between the cases where nickel and cobalt are added and a pure titanium dioxide film, and the dielectric constant is a little less than 90 in all of the cases. These values of dielectric constant are considered to be appropriate as the dielectric constant perpendicular to the c-axis of a rutile structure. Therefore, the addition of nickel or cobalt does not have any effect of increasing the dielectric constant in the case where the film thickness is large and on the order of 100 nm. This shows that the addition of nickel or cobalt does not have such an effect as might change the crystalline structure of titanium dioxide, that is, this shows that a fundamental crystalline structure is the rutile structure of titanium dioxide. In contrast, the addition of vanadium shows another behavior. Even when the film thickness is large, the dielectric constant of vanadium-added film is approximately 40, a value lower than that of the pure titanium dioxide film. This means that the crystalline structure of a vanadium-added film has changed from rutile to another structure. According to studies by the present inventors, the crystalline structure of a vanadium-added film tends to become a film which is such that a rutile structure and an anatase structure are mixed (not shown). As described earlier, an anatase structure has a dielectric constant of approximately 30 and it may be thought that this mixing effect caused a low dielectric constant of approximately 40.

Next, a case where these element-added titanium dioxide films are thinned is considered. As discussed in Exemplary Embodiment 1, in order that the films are applied to a DRAM, the physical film thickness has to be at least not more than 10 nm, because the films are built on an inner wall of a microstructural electrode. When the film thickness dependence of the dielectric constant of a pure titanium dioxide film is viewed from this point of view, there is observed the phenomenon that the dielectric constant decreases suddenly, with 50 nm thick being a threshold value.

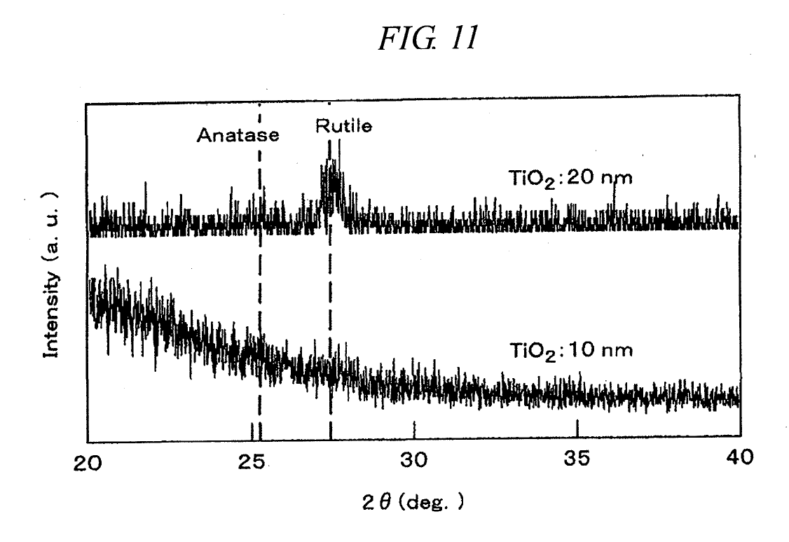

For this reason, in FIG. 9, even when the physical film thickness is reduced, capacitance does not show an increase that is indirectly proportional to film thickness but shows a tendency toward saturation. As a result of studies by the present inventors, it became evident that this deterioration of dielectric constant associated with a decrease in film thickness is caused by the rapidly losing of crystallinity associated with a decrease in film thickness. FIG. 11 shows an X-ray diffraction diagram of pure titanium dioxide films having film thicknesses of 20 nm and 10 nm. A peak intensity corresponding to that of rutile is observed at 20 nm, though weak, but no peak intensity is detected in the least at 10 nm thick. This shows that crystallinity becomes lost with decreasing film thickness. In a manner corresponding to this, as shown in FIG. 10, the dielectric constant of pure titanium dioxide decreases. In particular, for film thicknesses of not more than 10 nm, which are necessary for being adaptable to the microstructure of a DRAM, the dielectric constant of a pure titanium dioxide film is less than 30, below even the value of a thick film of an anatase structure.

On the other hand, although also in the case where cobalt or nickel is added, as shown in FIG. 10, a decrease in dielectric constant associated with a decrease in film thickness occurs, the film thickness at which the decrease begins is present on the thin film side compared to pure titanium dioxide and the rate of decrease is relatively gentle. As a result of this, in the range of 5 nm to 10 nm, which is a film thickness range useful for DRAMs, high dielectric constants of not less than 40 are maintained. It will be understood that this effect is due to the action of nickel or cobalt that assists in the crystallization into a rutile structure. The rutile phase of titanium dioxide has a higher symmetrical property than the anatase phase and hence the rutile phase is a thermodynamically stable structure. However, the activation energy necessary for the crystallization is also high, and it may be thought that when the film thickness is small, this activation energy increases further. If this activation energy decreases due to the addition of cobalt or nickel, it is possible to generate the rutile phase in a region of further reduced film thicknesses. The effect of the present invention is probably due to a decrease in this activation energy.

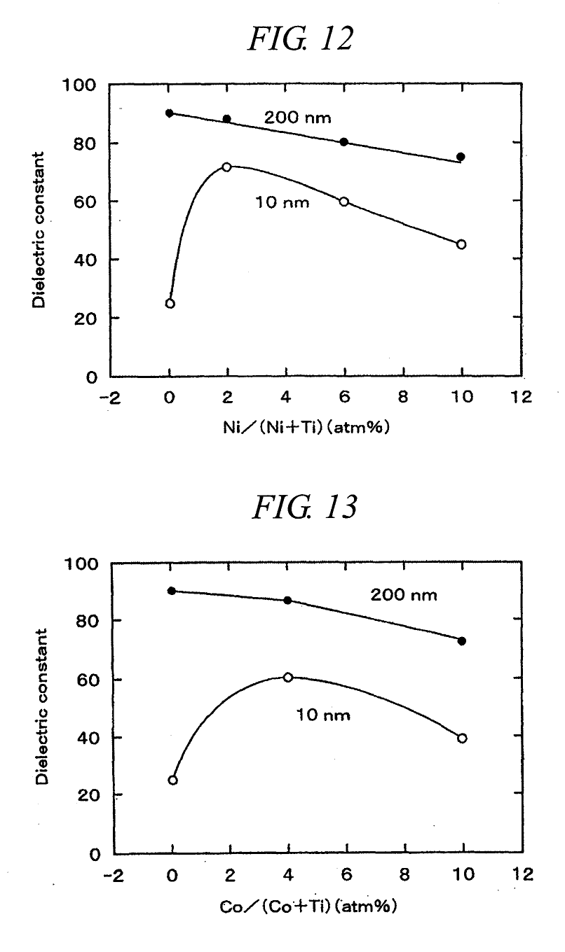

Next, a guideline for the selection of additive amounts of cobalt and nickel will be disclosed. In FIGS. 12 and 13, the measurements are plotted, with the composition ratio of nickel or cobalt as abscissa and the dielectric constant as ordinate, respectively. When the film thickness is large, that is, when the film thickness is 200 nm, in both additive elements, the dielectric constant shows a tendency to decrease with increasing amount of component. On the other hand, in the case of a practical film thickness (10 nm in FIGS. 12 and 13), the dielectric constant tends to increase rapidly in increasing additive amount and decrease after that. It will be understood that the addition produces the effect that the dielectric constant increases due to an improvement in crystallinity associated with the addition and the effect that the dielectric constant decreases due to excessive addition. Therefore, optimum values exist in additive amounts, and it is evident that the additive amount of nickel is preferably approximately 2% and that the additive amount of cobalt is preferably approximately 4%.

Incidentally, as described above, optimum values of additive amounts are determined by the dielectric constant. However, in terms of the application to microstructural DRAMs, it is effective to use a composition range in which superiority over zirconium dioxide (ε≅40), which is a related art, is obtained. From FIGS. 12 and 13, such composition ranges are from approximately 1% to 10% for both nickel and cobalt and it can be said that carrying out the present invention in such composition ranges is virtually effective. If the elements are added in amounts exceeding the upper limit of 10%, an increase in leakage current is remarkable, and obtained DRAM capacitors cannot be put to practical use. As shown in the following exemplary embodiment, if a practical film thickness is not more than 10 nm on the assumption that the formation by ALD is performed, then it is difficult to control the composition range to less than 0.5%. As described above, from the standpoint of practicality, it can be said that the effective composition range is 0.5% to 10%.

### Exemplary Embodiment 3

In this exemplary embodiment, there will be disclosed a method of forming the above-described element-added rutile TiO₂ by ALD, which is a film formation method suitable for DRAMs. First, it should be noted that a practical film thickness in DRAMs, for example, 10 nm corresponds to the stacking of approximately 20 layers of rutile phase TiO₂. Therefore, an additive amount of 5% is an amount corresponding to the replacement of Ti atoms equivalent to one layer among the 20 layers with the additive atoms.

First, a description will be given of the ALD method using titanium isopropoxide (Ti(i-C₃H₇O)₄, hereinafter abbreviated as TIPT) as a Ti raw material. If the substrate temperature is 250° C. and ozone is used as an oxidizing agent, it is possible to form a film in a thickness of 10 nm in 200 cycles and the deposition rate per cycle is 0.05 nm. When the length of an a-axis of the rutile phase (0.46 nm) is considered, approximately 10 cycles are necessary for the formation one layer of TiO₂. Similarly, if nickel acetylacetonato (Ni(acac)₂, hereinafter abbreviated as NM) is used as nickel, and if the substrate temperature is 250° C. and ozone is used as an oxidizing agent, the deposition rate becomes 0.05 nm/cycle, an almost equivalent value. Also for cobalt, ALD using cobalt acetylacetonato (Co(acac)₂, hereinafter abbreviated as CAA) is possible, and the deposition rate is on the order of 0.05 nm/cycle. As will be understood from these, when the raw materials handled in the present invention are deposited by the ALD method, the deposition rate becomes 0.05 nm/cycle regardless of the composition. Therefore, the required number of cycles is 200 cycles irrespective of the composition when the finished film thickness is 10 nm.

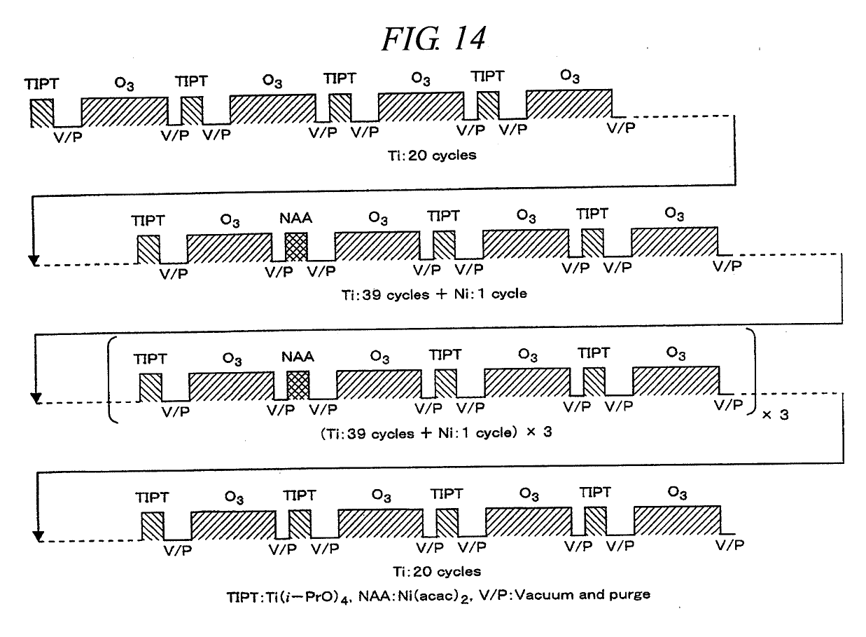

FIG. 14 shows a sequence for forming a 2% nickel-added titanium dioxide film having a finished film thickness of 10 nm. Here, “raw material gas supply+vacuuming/purging (V/P)+ozone supply (O₃)+vacuuming+purging” is counted as one cycle. Also, hereinafter, the cycle in which the raw material gas is a titanium raw material (TIPT) is referred to as “Ti cycle”, the cycle in which the raw material gas is a nickel raw material (NAA) is referred to as “Ni cycle”, and the cycle in which the raw material gas is a cobalt raw material (CAA) is referred to as “Co cycle”. If four Ni cycles are caused to be included in the total number of 200 cycles, then the additive amount of nickel becomes 2%. With reference to FIG. 14, first, the Ti cycle is singly performed 20 times, thereafter a sequence including one Ni cycle and 39 Ti cycles is repeated four times, and finally the Ti cycle alone is performed 20 times. Because four Ni cycles are included in the 200 cycles, a titanium dioxide film containing 2% nickel is formed.

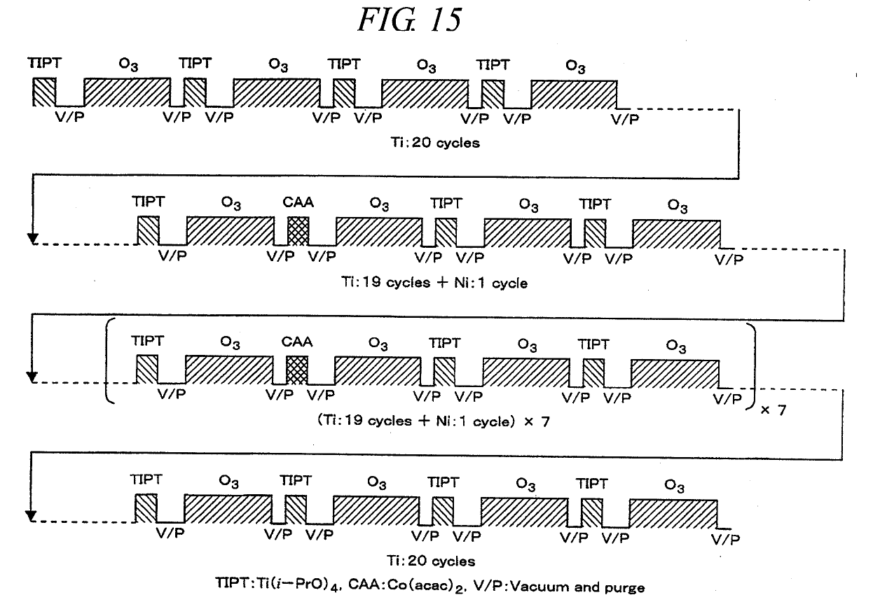

Similarly, FIG. 15 shows a sequence for forming a cobalt 4%-added titanium dioxide film. In this example, first, the Ti cycle is singly performed 20 times, thereafter a sequence including one Co cycle and 19 Ti cycles is repeated eight times, and finally the Ti cycle alone is performed 20 times. Because eight Co cycles are included in the 200 cycles, a titanium dioxide film containing 4% cobalt is formed.

The examples of FIGS. 14 and 15 are designed so that a titanium sequence including at least 20 Ti cycles alone is performed each after the start of deposition, between the Ni or Co cycles, and before the finish of deposition. Because sequencial 20 Ti cycles correspond to titanium dioxide of approximately 1 nm, a nickel layer or a cobalt layer is at least 1 nm apart from the electrode layer and a gap of at least 1 nm is placed also between nickel or cobalt layers. That is, there is a gap of at least 1 nm in the film thickness direction. For the horizontal direction, a cycle rate of 0.05 nm is equivalent to about 1/10 of the lattice gap and, therefore, the average horizontal distance between added elements is equivalent to about three times the lattice gap. Thus, also as this average distance, there is a distance of the order of 1 nm. Therefore, from the sequences of FIGS. 14 and 15, it is supposed that the added elements are positioned in places approximately 1 nm apart from each other.

The advantage of the sequences resides in the point that the added elements can be uniformly dispersed in the base metal of titanium dioxide as far as possible. Owing to this manner, it is possible to make the best possible use of the crystallization promoting effect of the added elements. However, because the diffusion of nickel and cobalt at the crystallization heat treatment temperature, which will be described later, is probably sufficiently fast, it should be noted that the adoption of the sequences is not indispensable for the effect of the present invention. These sequences are methods effective in minimizing the losing of the crystallization promoting effect and a local increase in leakage current, which are caused by the precipitation of the added elements on defect structures present at the electrode interfaces and at the grain boundaries of titanium dioxide.

When the compositions of the added elements take values other than the above-described 2% and 4%, the number of nickel sequences and cobalt sequences is appropriately increased or decreased. However, in the case of the above-described 200 cycles of deposition because of the adoption of ALD, one cycle corresponds to 0.5% in composition ratio and, therefore, it should be noted that compositions below this value cannot be controlled.

Although titanium isopropoxide was used here as a titanium raw material, examples of preferred titanium raw materials further include amide raw materials, such as titanium dimethylamide (Ti[N(CH₃)₂]₄), titanium diethylamide (Ti[N(C₂H₅)₂]₄) and titanium ethylmethylamide (Ti[N(CH₃)(C₂H₅)₄), and Ti(i-PrO)₂(thd)₂, which is a thd (2,2,6,6-tetramethyl-3,5-heptanedionate) complex raw material. Examples of other preferred raw materials of nickel include Ni(thd)₂, which is a thd complex, nickelocene (Ni(Cp)₂), which is a raw material for cyclopentadienyl (C₅H₅, abbreviated as Cp), bis(ethylcyclopentadienyl) nickel (Ni(EtCp)₂) and an amidinato complex (bis(N,N′-diisopropylacetamidinato)Ni). For cobalt, preferred raw materials include cobaltocene (bis(cyclopentadienyl) cobalt: Co(Cp)₂), bis(pentamethyl-cyclopentadienyl) cobalt (Co[(CH₃)₅Cp]₂) and bis(ethylcyclopentadienyl) cobalt (Co(C₂H₅Cp)₂) which is a cyclopentadienyl complex.

Although ozone was used as the oxidizing agent, ozone is supplied from an ozone generator, as is generally known. Therefore, in actuality, this is a mixed gas of oxygen containing several percent of ozone. It is also effective to raise the decomposition efficiency of the raw material by increasing the ozone concentration. It is also possible to use water as the oxidizing agent according to the selection of the raw material. Although the substrate temperature was 250° C., it is not limited to this temperature. So long as the temperature range meets what is called the ALD window (not less than the temperature at which the chemical adsorption of the raw material becomes dominant over the physical adsorption, but not more than the temperature at which the gas phase decomposition of the raw material occurs), the carrying out of the present invention is not impeded in the least.

An element-added titanium dioxide film thus formed is caused to crystallize by post-deposition heat treatment. Because the selection of crystallization conditions is determined by the heat resistance and oxidation resistance of the lower electrode, it depends greatly on the film forming method and film forming conditions of the lower electrode film. Crystallization conditions on a ruthenium electrode formed by ALD are shown here as an exemplary embodiment most preferred in terms of application. The ALD conditions are based on the sequences shown in FIGS. 14 and 15.

The first method is a combination of oxidizing treatment at relatively low temperatures and non-oxidizing treatment at temperatures exceeding the crystallization temperature. In this method, first, heat treatment at 400° C. to 500° C. is performed in an oxidizing atmosphere, preferably, in oxygen gas. This oxidizing treatment is performed mainly for the purpose of removing the carbon in the raw material that comes to be mixed in during the ALD process. Using active oxygen, such as oxygen plasma and ozone, in place of oxygen gas is also an effective exemplary embodiment of this method. After that, heat treatment at 600° C. to 700° C. is performed in a non-oxidizing atmosphere, preferably, in nitrogen or argon atmosphere. This non-oxidizing heat treatment is performed mainly for the purpose of causing titanium dioxide to crystallize into the rutile phase. Because this crystallization heat treatment is performed at high temperatures, the adoption of a lamp annealing method permitting rapid heating and cooling enables thermal loads to be substantially reduced and besides makes it possible to reduce the possibility of an increase in a junction leakage current of transistors, for example, that is caused by the diffusion of nickel or cobalt, which is an added element, to portions other than the capacitor structure.

The second method is a combination of non-oxidizing treatment at temperatures exceeding the crystallization temperature and low-temperature oxidizing treatment. In this method, first, heat treatment at 600° C. to 700° C. is performed in a non-oxidizing atmosphere, preferably, in nitrogen or argon atmosphere. In this treatment, titanium dioxide crystallizes into the rutile phase and the carbon contained as an impurity is discharged to the atmosphere in association with the crystallization. In this treatment, a lamp annealing method permitting rapid heating and cooling is effective and the transistor characteristics can be improved by reducing thermal loads and the possibility of contamination. After that, oxidizing heat treatment at 250° C. to 400° C. is performed. This oxidizing heat treatment is performed for the purpose of recovering oxygen losses present in titanium dioxide. If the temperature is too high, an erosion (oxidation) of ruthenium, which is the lower electrode, occurs. In the first method, the carbon remaining in the ALD film effectively consumes oxygen and, therefore, the oxidation of the lower electrode is less apt to occur relatively. In the second method, however, the carbon has already been removed by crystallization and, therefore, it is necessary to lower the temperature to a greater extent than in the oxidizing treatment of the first method. The use of active oxygen in this treatment is effective for this purpose of temperature lowering.

It is needless to say that appropriately combining the two methods, i.e., three-stage heat treatment involving oxidizing heat treatment, crystallization heat treatment and low-temperature oxidizing heat treatment is an effective exemplary embodiment. The amount of carbon remaining in the ALD process has a strong dependence on the V/P (vacuuming/purging) time and ozone supply time in FIGS. 14 and 15 and has also dependence on the type of a reaction furnace (piece-by-piece type/batch type). For this reason, it is necessary to optimize heat treatment conditions by appropriately combining the methods of the present invention.

### Exemplary Embodiment 4

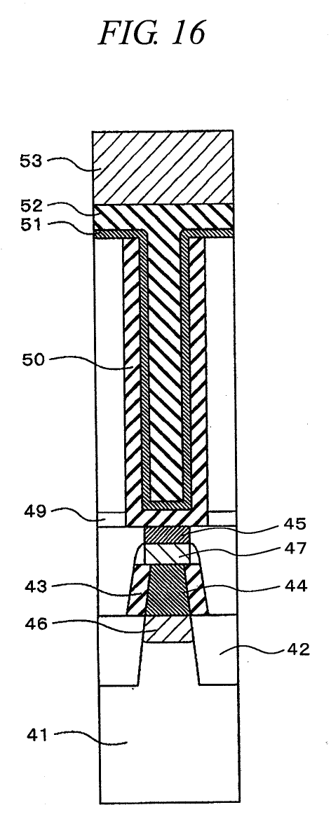

Next, an exemplary embodiment having another memory cell structure will be disclosed as one of the exemplary embodiments. FIG. 16 is a sectional view of a semiconductor storage device, i.e., a DRAM in an exemplary embodiment. In this exemplary embodiment, there is a columnar structure (or a pillar) of silicon that is built up perpendicularly to the plane of substrate 41, and a gate electrode is arranged so as to surround this columnar structure via a gate insulating film, which is not shown. In this structure, a lower diffusion layer that becomes bit line 46 is formed in the base portion of the columnar structure, and the gate electrode surrounding the columnar structure is word line 43. Plug 45 drawn from the top portion of the columnar structure via upper diffusion layer 47 is connected to lower electrode 50 of a capacitor. The capacitor structure is the same as in FIG. 1. A PN junction is formed each at a contact interface between the columnar structure and the lower diffusion layer and a contact interface between the columnar structure and the upper diffusion layer.

If the minimum fabrication dimension is denoted by F in this structure, the occupied area per bit can be made 4F². Because the occupied area of the DRAM cell shown in FIG. 1 is 6F² at a minimum, by adopting the structure of FIG. 16, it is possible to increase the capacity of the memory cell 50% while using the same microfabrication technique.

However, it is necessary to pay attention to the fact that the effective electrode area of a capacitor decreases in proportion to the square root of the occupied area per bit. That is, although in the structure of FIG. 1 it was possible to-make a structure having a capacitor opening of 60 nm width and 2 μm depth, in the structure of this exemplary embodiment, an opening width of the order of 50 nm is obtained. As a result of this reduction of the opening width, the opening depth for obtaining an equivalent capacitance becomes 2.4 μm.

Next, the fabrication method of this DRAM cell will be described in detail.

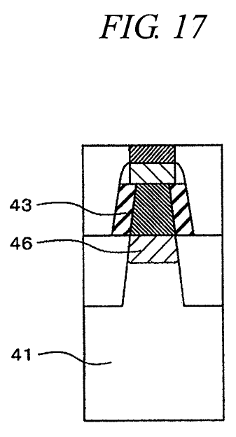

FIG. 17 shows a section obtained when the formation of a transistor of the memory cell, word line 43, bit line 46 and an interconnect plug to a lower capacitor electrode has been completed. There is the columnar transistor on silicon substrate 41, and word line 34 also serving as a gate electrode is formed so as to surround this columnar structure.

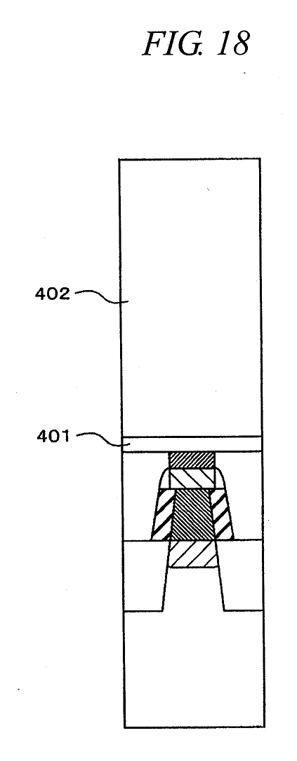

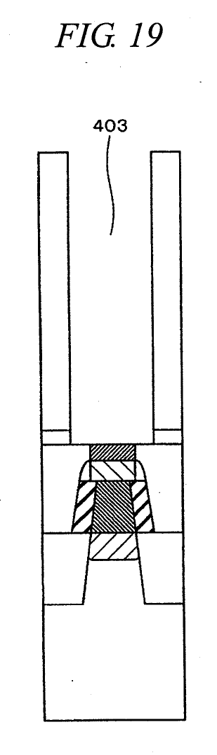

Next, an interlayer insulating film that determines the height of the capacitor electrode is deposited on the structure of FIG. 17. In this exemplary embodiment, silicon nitride layer 401 as etching stopper layer 49 shown in FIG. 16 and silicon oxide layer 402 are stacked. Silicon nitride layer 401 is deposited in thicknesses of 5 nm to 10 nm by the CVD method (see FIG. 18). After that, silicon oxide layer 402 is stacked in a thickness of 2.4 μm by the plasma CVD method using tetraethoxysilane and oxygen as raw materials. Silicon oxide layer 402 and silicon nitride layer 401 of portion 403 where a capacitor is to be formed are removed by photolithography and dry etching, whereby the structure of FIG. 19 is obtained. In FIGS. 16 to 23, to allow the FiGures to be seen easily, the film thickness and the length-to-width ratio are expressed on any given basis. However, because the formed hole structures are such that the diameter of the opening is approximately 50 nm and the height is 2.4 μm, the ratio of the opening width to the depth (hereinafter referred to as the aspect ratio) is close to 50. The hole structure is deeper than in FIG. 1.

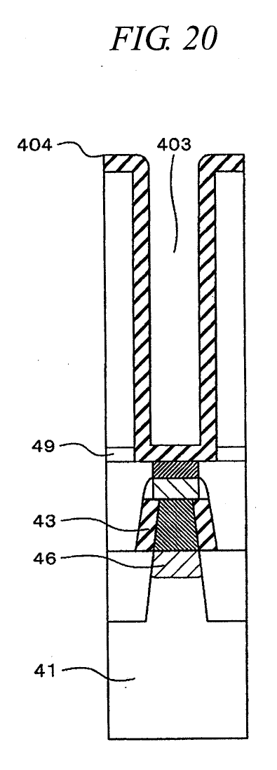

Next, ruthenium that becomes lower electrode 50 was deposited in a thickness of 10 nm by the CVD method (see FIG. 20). Although this ruthenium layer 404 is deposited by the CVD method using ethylcyclopentadienyl ruthenium (Ru(EtCp)₂) and oxygen, ruthenium deposited by ALD is also preferable. Although the deposition rate is lower than in the CVD method, the ALD method can take advantage of its feature of excellent step coverage when it is necessary to form uniformly a film also on the inner wall and bottom part of a structure having a very large aspect ratio as described above.

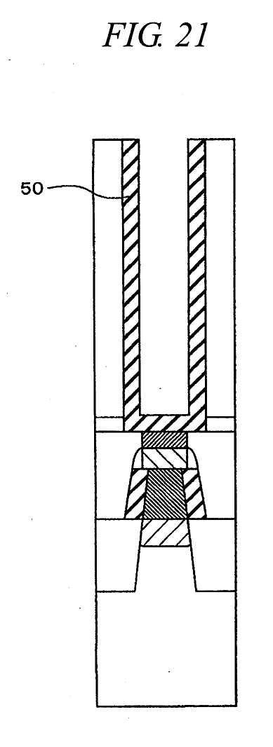

The etch back process is then performed in order to divide this lower electrode for each bit. After the application of a positive type photoresist onto the structure of FIG. 20, the whole chip surface is exposed by development, whereby the resist on silicon oxide film 402 is removed and an unexposed photoresist remains in the interior of hole structure 403. When this structure is dry etched, only the ruthenium layer between bits is removed and as shown in FIG. 21, a structure in which lower electrode 50 is divided for each bit can be formed.

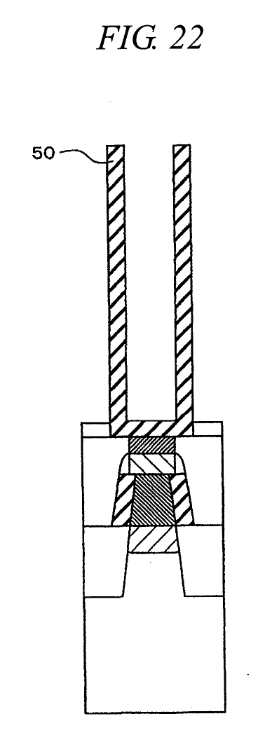

Silicon oxide layer 402 is removed by wet etching and the photoresist is removed, whereby it is also possible to form lower electrode structure 50 in which only ruthenium layer 404 remains in columnar shape. In this case, it is possible to use also the external wall as the capacitor electrode (see FIG. 22). Although a case where silicon oxide 402 is not removed is illustrated below, the same steps are used.

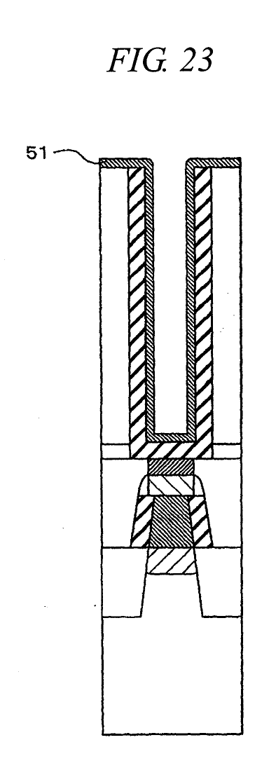

Next, titanium dioxide layer 51 to which cobalt or nickel is added is formed in a thickness of 6 nm (see FIG. 23). After the finish of deposition, the titanium dioxide was caused to crystallize into rutile by two-stage heat treatment. The dielectric constant after the recrystallization was 60 for cobalt addition and 70 for nickel addition. Furthermore, ruthenium is formed by ALD as upper electrode 52. For the purpose of lowering the sheet resistance as a plate electrode, tungsten film 53 is formed by the sputtering method, whereby the structure shown in FIG. 16 is completed.

Because the depth was increased to 2.4 μm to adapt to the declease of the occupied area, it is possible to ensure an accumulation capacitance of 25 fF when a 4% cobalt-added titanium dioxide film having a thickness of 6 nm is used and an accumulation capacitance of 30 fF when a 2% nickel-added titanium dioxide film is used. The leakage current obtained when in these capacitors a voltage of 0.5 V is applied across both electrodes is less than 1 fA per bit, and it is possible to make the refresh action intervals sufficiently long.

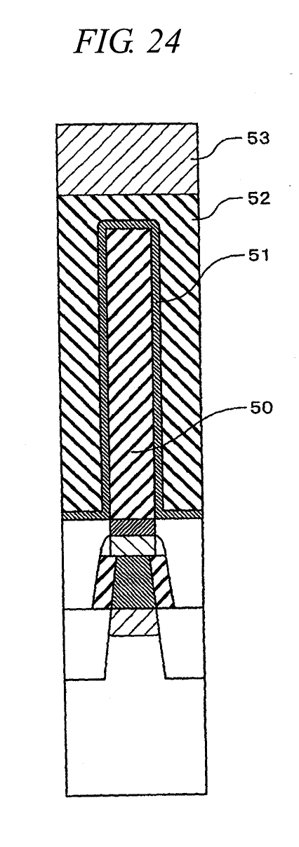

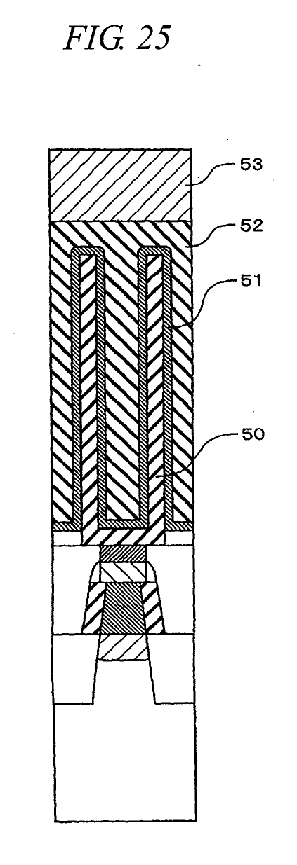

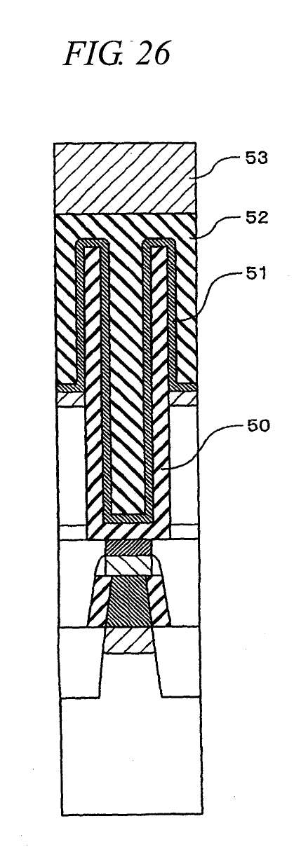

Incidentally, in this exemplary embodiment, as in FIG. 1, a capacitor in which an inner wall in the shape of a hole opening in silicon oxide layer 402 is used was adopted. However, a structure in which titanium dioxide layer 51 is formed on an external wall of lower electrode 50 as a columnar structure as shown in FIG. 24, a structure in which also an internal and external wall of a lower electrode is used as a capacitor as shown in FIG. 25, and a structure in which part of an external wall of a lower electrode is used as a capacitor as shown in FIG. 26 are also effective exemplary embodiments.

What is claimed is:

1. A semiconductor storage device provided with a DRAM cell comprising a capacitor in which a lower electrode, a dielectric film and an upper electrode are stacked on a substrate in this order,
wherein the dielectric film comprises titanium oxide as a main component and further comprises at least either nickel or cobalt.

2. The semiconductor storage device according to claim 1,
wherein the dielectric film has a film thickness of not more than 10 nm and crystallizes into a rutile structure.

3. The semiconductor storage device according to claim 1,
wherein not less than 90 atomic percent of metallic elements contained in the dielectric film are titanium.

4. The semiconductor storage device according to claim 1,
wherein 0.5 atomic percent to 10 atomic percent of metallic elements contained in the dielectric film are nickel.

5. The semiconductor storage device according to claim 1,
wherein 0.5 atomic percent to 10 atomic percent of metallic elements contained in the dielectric film are cobalt.

6. The semiconductor storage device according to claim 1,
wherein at least either the lower electrode or the upper electrode comprises ruthenium, iridium, or platinum as a main component.

7. A method of manufacturing a semiconductor storage device, comprising:
forming a well structure after formation of an isolation structure on a semiconductor substrate;
forming a word line that serves as a gate electrode on the semiconductor substrate;
forming an interlayer insulating film on the semiconductor substrate;
forming a contact plug that connects to the word line by passing through the interlayer insulating film;
forming a bit line that connects to the contact plug on the interlayer insulating film; and
forming a capacitor by forming a lower electrode on the interlayer insulating film, forming a dielectric film on the lower electrode and further forming an upper electrode on the dielectric film,
wherein the dielectric film comprises titanium oxide as a main component and further comprises at least either nickel or cobalt.

8. The method of manufacturing a semiconductor storage device according to claim 7, wherein the forming of the dielectric film comprises:
a first stage for depositing a thin film by repeating a plural of times a cycle that involves supplying a raw material gas containing titanium, vacuuming/purging, supplying ozone, and vacuuming/purging, and
a second stage for depositing nickel or cobalt by performing one cycle that involves supplying a raw material gas containing nickel or cobalt, vacuuming/purging, supplying ozone, and vacuuming/purging after one prescribed cycle of the first stage.

9. The method of manufacturing a semiconductor storage device according to claim 8, wherein the number of cycles of the first stage is determined according to the thickness of the dielectric film and the number of cycles of the second stage is determined according to the additive amount of nickel or cobalt added to the dielectric film.

10. A method of manufacturing a semiconductor storage device, comprising:
forming a well structure after formation of an isolation structure on a semiconductor substrate;
forming a diffusion layer that becomes a bit line on the semiconductor substrate;
forming a pillar including two PN junctions on the semiconductor substrate so as to connect to the diffusion layer;
forming a word line that serves as a gate electrode on the side wall of the pillar; and
forming a capacitor by forming a first electrode on the pillar, forming a dielectric film on a surface of the first electrode, and further forming a second electrode on a surface of the dielectric film,
wherein the dielectric film comprises titanium oxide as a main component and further comprises at least either nickel or cobalt.

11. The method of manufacturing a semiconductor storage device according to claim 10, wherein the forming of the dielectric film comprises:
a first stage for depositing a thin film by repeating a plural of times a cycle that involves supplying a raw material gas containing titanium, vacuuming/purging, supplying ozone, and vacuuming/purging, and
a second stage for depositing nickel or cobalt by performing one cycle that involves supplying a raw material gas containing nickel or cobalt, vacuuming/purging, supplying ozone, and vacuuming/purging after one prescribed cycle of the first stage.

12. The method of manufacturing a semiconductor storage device according to claim 11, wherein the number of cycles of the first stage is determined according to the thickness of the dielectric film and the number of cycles of the second stage is determined according to the additive amount of nickel or cobalt added to the dielectric film.

13. A semiconductor storage device provided with a DRAM cell comprising a capacitor in which a lower electrode, a dielectric film and an upper electrode are stacked on a substrate in this order,
wherein the dielectric film comprises titanium oxide as a main component, and has a rutile structure with a film thickness of not more than 10 nm.

14. The semiconductor storage device according to claim 13,
wherein the dielectric film further comprises at least either nickel or cobalt as an additive element.

15. The semiconductor storage device according to claim 14, wherein 0.5 atomic percent to 10 atomic percent of metallic elements contained in the dielectric film are the additive element and remaining metallic elements are titanium.

16. The semiconductor storage device according to claim 13,
wherein the dielectric film has a dielectric constant of 40 or more.

17. The semiconductor storage device according to claim 13,
wherein at least either the lower electrode or the upper electrode comprises ruthenium, iridium, or platinum as a main component.

18. The semiconductor storage device according to claim 13,
wherein the lower electrode is formed in a cylindrical structure and the dielectric film is formed on at least inner wall of the cylindrical structure.

19. The semiconductor storage device according to claim 13,
wherein the lower electrode is formed in a columnar structure and the dielectric film is formed on the external wall of the columnar structure.

20. A method of manufacturing a semiconductor storage device provided with a DRAM cell comprising a capacitor in which a lower electrode, a dielectric film and an upper electrode are stacked on a substrate in this order, the method comprising:
depositing a titanium oxide layer containing at least either nickel or cobalt as an additive element on the lower electrode, and
crystallizing the titanium oxide layer into a rutile structure to form the dielectric film.

21. The method of manufacturing a semiconductor storage device according to claim 20, wherein the deposition of the titanium oxide layer is performed by an atomic layer deposition technique that involves supplying a raw material gas, vacuuming/purging, supplying ozone, and vacuuming/purging as one cycle, and the deposition comprises:
a first stage for repeating a plural of times the cycle by using titanium-containing raw material gas, and
a second stage for performing one time the cycle by using a raw material gas containing nickel or cobalt after one prescribed cycle of the first stage.

22. The method of manufacturing a semiconductor storage device according to claim 21, wherein the second stage is repeated by interposing at least 20 cycles of the first stage, before the first performed second stage, between cycles of the second stage and after the last performed second stage, to introduce the additive element with an amount of 0.5 atomic percent to 10 atomic percent based on the total number of metallic elements into the dielectric film.

23. The method of manufacturing a semiconductor storage device according to claim 21, wherein the deposition temperature is 250° C. to 350° C.

24. The method of manufacturing a semiconductor storage device according to claim 20, wherein the crystalization of the titanium oxide layer into a rutile structure comprises at least two-stage heat treatment.

25. The method of manufacturing a semiconductor storage device according to claim 24, wherein the at least two-stage heat treatment comprises a first heat stage at 400° C. to 500° C. in an oxidizing atmosphere and a second heat stage at 600 to 700° C. in a non-oxidizing atmosphere in this order.

26. The method of manufacturing a semiconductor storage device according to claim 25, wherein the at least two-stage heat treatment further comprises a therd heat stage at 250° C. to 400° C. in an oxidizing atmosphere after the second heat stage.

27. The method of manufacturing a semiconductor storage device according to claim 24, wherein the at least two-stage heat treatment comprises a first heat stage at 600° C. to 700° C. in a non-oxidizing atmosphere and a second heat stage at 250° C. to 400° C. in an oxidizing atmosphere in this order.
